(19) United States
(12) Patent Application Publication
(10) Pub. No.: US 2020/0115227 A1
(43) Pub. Date: Apr. 16, 2020

(54) METHOD OF MANUFACTURING SEMICONDUCTOR DEVICE

(71) Applicant: KOKUSAI ELECTRIC CORPORATION, Tokyo (JP)

(72) Inventors: Naofumi OHASHI, Toyama-shi (JP); Yoshiro HIROSE, Toyama-shi (JP)

(73) Assignee: KOKUSAI ELECTRIC CORPORATION, Tokyo (JP)

(21) Appl. No.: 16/572,677

(22) Filed: Sep. 17, 2019

(30) Foreign Application Priority Data
Sep. 25, 2018 (JP) 2018-178991

(51) Int. Cl. B81C 1/00; H01L 21/02

(52) U.S. Cl. CPC B81C 1/00539; H01L 21/02164; B81C 1/0015; B81C 1/00531

(57) ABSTRACT

Described herein is a technique capable of forming a sacrificial film with a high wet etching rate to obtain a wet etching selectivity with respect to a movable electrode when manufacturing a cantilever structure sensor using MEMS (Micro-Electro-Mechanical Systems) technology. According to one aspect of the technique of the present disclosure, there is provided a method of manufacturing a semiconductor device including: (a) loading a substrate including a control electrode, a pedestal and a counter electrode formed thereon into a process chamber; and (b) forming a sacrificial film containing impurities on the control electrode, the pedestal and the counter electrode by supplying a first process gas in a non-plasma state containing the impurities and silicon to the process chamber through a first gas supply pipe together with supplying a second process gas in a plasma state containing oxygen to the process chamber through a second gas supply pipe.

### CROSS-REFERENCE TO RELATED PATENT APPLICATION

This non-provisional U.S. patent application claims priority under 35 U.S.C. § 119 of Japanese Patent Application No. 2018-178991 filed on Sep. 25, 2018, in the Japanese Patent Office, the entire contents of which are hereby incorporated by reference.

### BACKGROUND

### 1. Field

The present disclosure relates to a method of manufacturing a semiconductor device.

### 2. Description of the Related Art

Recently, a sensor using MEMS (Micro-Electro-Mechanical Systems) technology has been produced as one of semiconductor devices. For example, a cantilever structure is used to form the sensor. According to related arts, a method of manufacturing a switch employing the cantilever structure is disclosed. According to the related arts, the method of manufacturing the switch including forming a movable electrode by a dry etching process and then etching a sacrificial film formed below the movable electrode by a wet etching process is disclosed.

As described above, the movable electrode of the cantilever structure is formed by the dry etching process. However, as a result of intensive research, the inventors of the present application discovered that constituent materials of the movable electrode may deteriorate due to the dry etching process.

When a wet etching rate of the movable electrode is decreased by the deterioration of the movable electrode, the wet etching rate of the movable electrode may approach a wet etching rate of the sacrificial film. Therefore, the movable electrode may also be etched when the sacrificial film is etched by the wet etching process.

### SUMMARY

Described herein is a technique capable of forming a sacrificial film with a high wet etching rate so as to obtain a wet etching selectivity with respect to a movable electrode when manufacturing a cantilever structure sensor.

According to one aspect of the technique of the present disclosure, there is provided a method of manufacturing a semiconductor device including: (a) loading a substrate including a control electrode, a pedestal and a counter electrode formed thereon into a process chamber; and (b) forming a sacrificial film containing impurities on the control electrode, the pedestal and the counter electrode by supplying a first process gas in a non-plasma state containing the impurities and silicon to the process chamber through a first gas supply pipe together with supplying a second process gas in a plasma state containing oxygen to the process chamber through a second gas supply pipe.

### BRIEF DESCRIPTION OF THE DRAWINGS

FIGS. 1A through 1F schematically illustrate a processing state of a substrate, respectively, according to one or more embodiments described herein.

FIGS. 2A through 2D schematically illustrate a processing state of the substrate, respectively, according to the embodiments described herein.

FIG. 3 schematically illustrates a vertical cross-section of a substrate processing apparatus according to the embodiments described herein.

FIG. 4 is a block diagram schematically illustrating a configuration of a controller and related components of the substrate processing apparatus according to the embodiments described herein.

FIG. 5 schematically illustrates a processing state of a sacrificial film according to the embodiments described herein.

FIG. 6 schematically illustrates a modification state of the sacrificial film according to the embodiments described herein.

FIG. 7 schematically illustrates a processing state of a sacrificial film according to a comparative example.

FIG. 8 schematically illustrates a modification state of the sacrificial film according to the comparative example.

FIG. 9 is a flow chart schematically illustrating a substrate processing according to the embodiments described herein.

### DETAILED DESCRIPTION

### Embodiments

Hereinafter, one or more embodiments (hereinafter, simply referred to as “embodiments”) according to the technique of the present disclosure will be described with reference to the drawings.

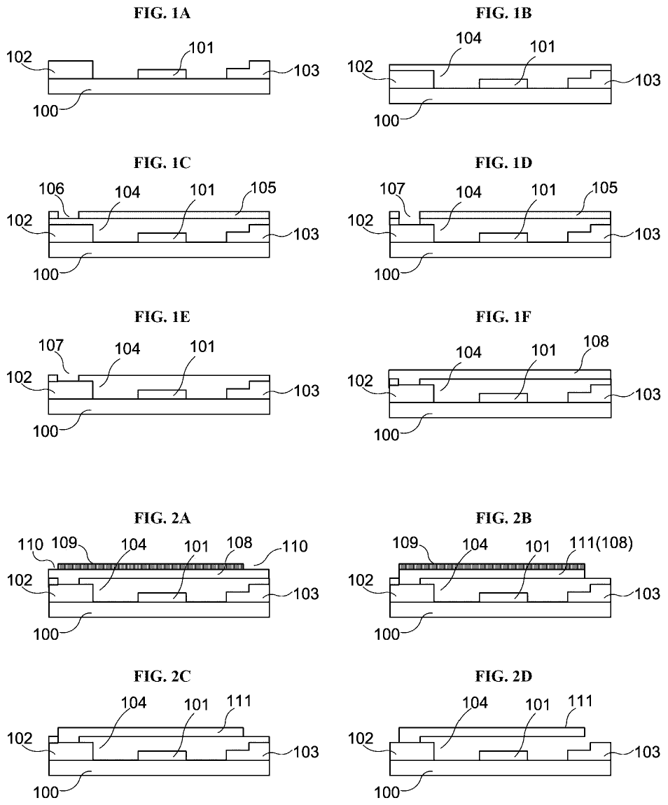

A configuration of a substrate to be processed according to the embodiments will be described with reference to FIGS. 1A through 2D. That is, a method of manufacturing an MEMS switch employing a cantilever structure will be described with reference to FIGS. 1A through 2D. The substrate in a processing state shown in FIG. 1A is processed in order from a processing state shown in FIG. 1B to a processing states shown in FIG. 1F. Then, the substrate in the processing state shown in FIG. 1F is processed in order from a processing state shown in FIG. 2A to a processing state shown in FIG. 2D.

A substrate 100 shown in FIG. 1A will be described. Referring to FIG. 1A, a control electrode 101, a pedestal (which may be a base or a support) 102 and a counter electrode 103 are formed on the substrate 100. The control electrode 101 is configured to control a movable electrode 111 described later, the pedestal 102 is configured to support the movable electrode 111, and the counter electrode 103 is an electrode paired with the movable electrode 111. Details thereof will be described later.

FIG. 1B schematically illustrates a processing state of the substrate 100 when a sacrificial film 104 is formed on the substrate 100 on which the control electrode 101, the pedestal 102 and the counter electrode 103 are formed. The sacrificial film 104 is removed later so as to enable the operation of the movable electrode 111. The method of forming the sacrificial film 104 will be described later.

FIG. 1C schematically illustrates a processing state of the substrate 100 when a photoresist 105 is formed on the sacrificial film 104 and a pattern is further formed.

FIG. 1D schematically illustrates a processing state of the substrate 100 when the sacrificial film 104 is etched by a dry etching process in accordance with a shape of the pattern 106. Thereby, a hole 107 is formed such that a surface of the pedestal 102 is exposed. For example, a known plasma etching process is performed as the dry etching process.

FIG. 1E schematically illustrates a processing state of the substrate 100 when the photoresist 105 is removed. For example, the photoresist 105 is removed by a known plasma ashing process.

FIG. 1F schematically illustrates a processing state of the substrate 100 when a polysilicon film 108 is formed on the pedestal 102 and the sacrificial film 104. The polysilicon film 108 is processed later to form the movable electrode 111. The polysilicon film 108 is electrically connected to the pedestal 102.

Subsequently, processing states of the substrate 100 will be described with reference to FIGS. 2A through 2D. FIG. 2A schematically illustrates a processing state of the substrate 100 when a photoresist 109 is formed on the polysilicon film 108 and a pattern 110 is further formed after the processing state shown in FIG. 1F.

FIG. 2B schematically illustrates a processing state of the substrate 100 when the polysilicon film 108 is etched by a dry etching process in accordance with a shape of the pattern 110. Thereby, the polysilicon film 108 is processed into a shape of the movable electrode 111. For example, a known plasma etching process is performed as the dry etching process.

FIG. 2C schematically illustrates a processing state of the substrate 100 when the photoresist 109 is removed. For example, the photoresist 109 is removed by a known plasma ashing process.

FIG. 2D schematically illustrates a processing state of the substrate 100 when the sacrificial film 104 is removed by a wet etching process. Thereby, the movable electrode 111, the control electrode 101 and the counter electrode 103 are separated from each other.

Hereinafter will be described problems of the above-mentioned method of manufacturing the MEMS switch discovered by the inventors of the present application. In the method described above, for example, the polysilicon film 108 is etched by the plasma etching process as shown in FIGS. 2A and 2B, or the photoresist 109 is removed by the plasma ashing process as shown in FIGS. 2B and 2C. During the plasma etching process or the plasma ashing process, the polysilicon film 108 is exposed to plasma to be damaged and deteriorated, and as a result, the strength thereof is decreased.

A wet etching rate of the deteriorated polysilicon film 108 is increased. Therefore, wet etching rates of the sacrificial film 104 and the movable electrode 111 approach each other. Then, when the sacrificial film 104 is etched by the wet etching process, the deteriorated portion of the polysilicon film 108 is also etched. When electric power is supplied to the movable electrode 111 in a state where the deteriorated portion of the polysilicon film 108 is also etched, the electric power may be concentrated on the deteriorated portion of the polysilicon film 108 or the electric power may not propagate easily.

In order to address the problems described above, it is required to obtain a wet etching selectivity such that a wet etching rate of the sacrificial film 104 is different from that of the movable electrode 111. Therefore, according to the embodiments, the sacrificial film 104 with a wet etching rate higher than that of the processed polysilicon film 108 is formed.

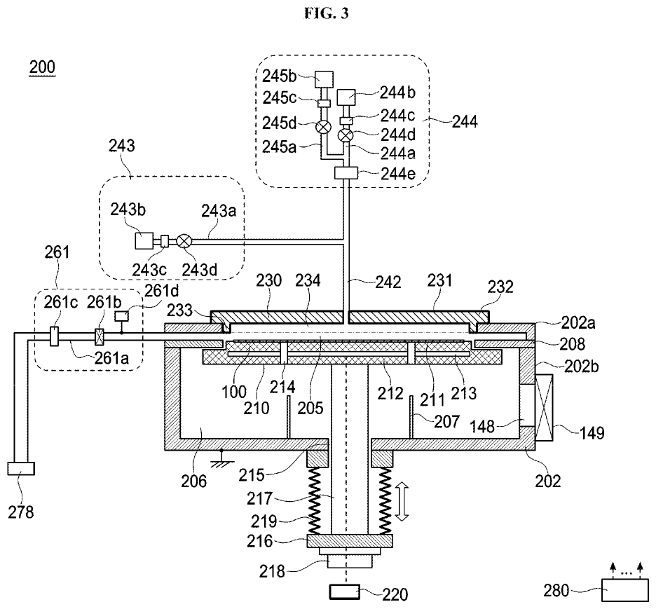

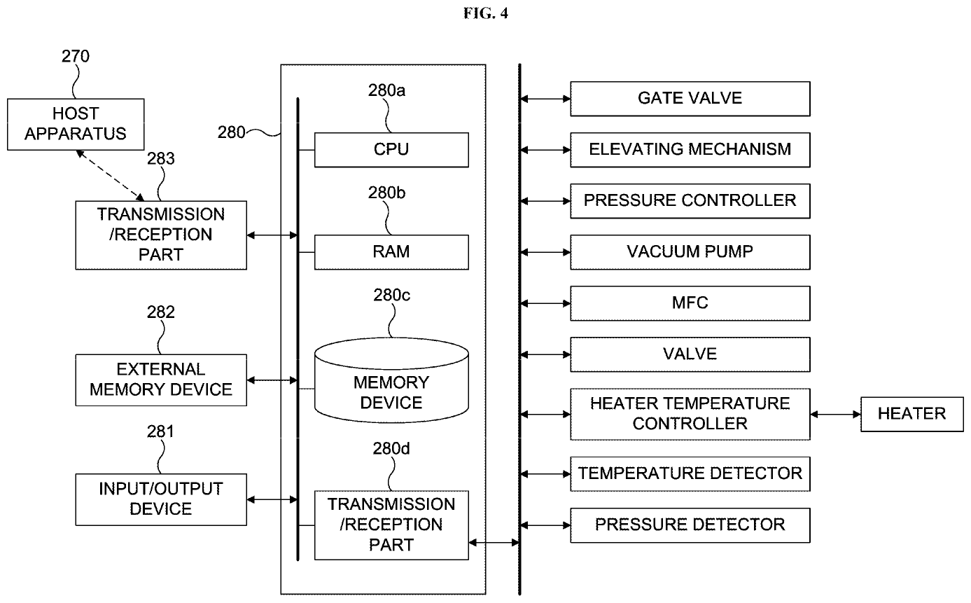

Hereinafter, an example of a substrate processing apparatus 200 of forming the sacrificial film 104 will be described with reference to FIG. 3.

<Chamber>

First, a chamber 202 will be described. The substrate processing apparatus 200 includes the chamber 202. For example, the chamber 202 is configured as a flat and sealed vessel with a circular horizontal cross-section. For example, the chamber 202 is made of a metal material such as aluminum (Al) and stainless steel (SUS). A process space 205 where the substrate 100 such as a silicon substrate is processed and a transfer space 206 through which the substrate 100 is transferred into the process space 205 are provided in the chamber 202. The chamber 202 includes an upper vessel 202a and a lower vessel 202b. A partition plate 208 is provided between the upper vessel 202a and the lower vessel 202b. The substrate 100 to be processed by the substrate processing apparatus 200 is in the processing state as shown in FIG. 1A. Therefore, the control electrode 101, the pedestal 102 and the counter electrode 103 are formed on the substrate 100.

A substrate loading/unloading port 148 is provided on a side surface of the lower vessel 202b adjacent to a gate valve 149. The substrate 100 is transferred between a vacuum transfer chamber (not shown) and the transfer space 206 through the substrate loading/unloading port 148. Lift pins 207 are provided at a bottom of the lower vessel 202b. The lower vessel 202b is electrically grounded.

A process chamber constituting the process space 205 is constituted by, for example, a shower head 230 and a substrate support table 212 which will be described later. A substrate support 210 capable of supporting the substrate 100 is provided in the process space 205. The substrate support 210 mainly includes the substrate support table 212 having a substrate placing surface 211 on which the substrate 100 is placed and a heater 213 serving as a heating source embedded in the substrate support table 212. Through-holes 214 penetrated by the lift pins 207 are provided at the substrate support table 212 corresponding to the locations of the lift pins 207. A temperature controller 220 capable of controlling a temperature of the heater 213 is connected to the heater 213.

The substrate support table 212 is supported by a shaft 217. A support portion of the shaft 217 penetrates a hole provided at a bottom of the chamber 202. The shaft 217 is connected to an elevating mechanism 218 outside the chamber 202 via a support plate 216. The substrate 100 placed on the substrate placing surface 211 is elevated and lowered by operating the elevating mechanism 218 by elevating and lowering the shaft 217 and the substrate support table 212. A bellows 219 covers a periphery of a lower end of the shaft 217. As a result, the interior of the chamber 202 is maintained airtight.

When the substrate 100 is transferred, the substrate support table 212 is moved downward until the substrate placing surface 211 faces the substrate loading/unloading port 148 (that is, the substrate support table 212 is moved to a substrate transfer position). When the substrate 100 is processed, the substrate support table 212 is moved upward until the substrate 100 reaches a substrate processing position in the process space 205 as shown in FIG. 3.

Specifically, when the substrate support table 212 is lowered to the substrate transfer position, upper end portions of the lift pins 207 protrude from an upper surface of the substrate placing surface 211, and the lift pins 207 support the substrate 100 from thereunder. When the substrate support table 212 is elevated to the substrate processing position, the lift pins 207 are buried from the upper surface of the substrate placing surface 211 and the substrate placing surface 211 supports the substrate 100 from thereunder.

The shower head 230 is provided above (upstream side of) the process chamber. The shower head 230 includes a cover 231. The cover 231 includes a flange 232. The flange 232 is supported by the upper vessel 202a. The cover 231 also includes a position guiding protrusion 233. The cover 231 is fixed by the position guiding protrusion 233 being engaged with the upper vessel 202a.

The shower head 230 includes a buffer space 234. The buffer space 234 refers to a space defined by the cover 231 and the position guiding protrusion 233. The buffer space 234 is spatially in communication with the process space 205. A gas supplied into the buffer space 234 is diffused in the buffer space 234 and uniformly supplied to the process space 205. According to the embodiments, the buffer space 234 and the process space 205 are separate spaces. However, the embodiments are not limited thereto. For example, the buffer space 234 may be included in the process space 205.

The process space 205 is defined by the upper vessel 202a and an upper structure of the substrate support table 212 at the substrate processing position. Structures defining the process space 205 may also be referred to as the process chamber. The structures defining the process space 205 are not limited to the above configuration as long as the process space 205 can be defined thereby.

The transfer space 206 is defined by the lower vessel 202b and a lower structure of the substrate support table 212 at the substrate processing position. Structures defining the transfer space 206 may also be referred to as a “transfer chamber”, and the transfer chamber is provided under the process chamber. The structures defining the transfer space 206 are not limited to the above configuration as long as the transfer space 206 can be defined thereby.

<Gas Supply System>

Next, a gas supply system will be described. A first gas supply pipe 243a and a second gas supply pipe 244a are connected to a common gas supply pipe 242.

A first process gas is supplied mainly though a first gas supply system 243 including the first gas supply pipe 243a. A second process gas is supplied mainly though a second gas supply system 244 including the second gas supply pipe 244a.

<First Gas Supply System>

A first gas supply source 243b, a mass flow controller (MFC) 243c serving as a flow rate controller (flow rate control mechanism) and a valve 243d serving as an opening/closing valve are provided at the first gas supply pipe 243a in order from an upstream side to a downstream side of the first gas supply pipe 243a.

A gas containing a first element (hereinafter, also referred to as the “first process gas” or a “first element-containing gas”) is supplied into the shower head 230 via the first gas supply pipe 243a provided with the MFC 243c and the valve 243d and the common gas supply pipe 242.

The first process gas is one of process gases. For example, the first process gas may include a gas containing silicon (Si) and impurities such as carbon (C) and boron (B). That is, the first process gas is also referred to as a “silicon-containing gas”. For example, tetraethyl orthosilicate (Si(OC₂H₅)₄, also referred to as “TEOS”) gas may be used as the silicon-containing gas.

The first gas supply system (also referred to as a “silicon-containing gas supply system”) 243 is constituted mainly by the first gas supply pipe 243a, the MFC 243c and the valve 243d.

The first gas supply system may further include the first gas supply source 243b.

<Second Gas Supply System>

A reactive gas supply source 244b, a mass flow controller (MFC) 244c serving as a flow rate controller (flow rate control mechanism) and a valve 244d serving as an opening/closing valve are provided at the second gas supply pipe 244a in order from an upstream side to a downstream side of the second gas supply pipe 244a. A remote plasma mechanism (also referred to as a “remote plasma unit” or “RPU”) 244e serving as a plasma generator may be provided at a downstream side of the valve 244d of the second gas supply pipe 244a to activate a reactive gas into a plasma state.

The reactive gas (hereinafter, also referred to as a “second process gas” or a “second element-containing gas”) is supplied into the shower head 230 via the second gas supply pipe 244a provided with the MFC 244c and the valve 244d and the common gas supply pipe 242. For example, the reactive gas may be activated into the plasma state by the RPU 244e and then is supplied into the shower head 230.

The reactive gas is one of the process gases. For example, the reactive gas may include an oxygen-containing gas. For example, oxygen (O₂) gas may be used as the oxygen-containing gas.

The second gas supply system (also referred to as a “reactive gas supply system”) 244 is constituted mainly by the second gas supply pipe 244a, the mass flow controller 244c, the valve 244d and the RPU 244e. The second gas supply system 244 may further include the reactive gas supply source 244b and a dilution gas supply system which will be described later.

A downstream end of a dilution gas supply pipe 245a is connected to the second gas supply pipe 244a at a downstream side of the valve 244d provided at the second gas supply pipe 244a. A dilution gas supply source 245b, a mass flow controller (MFC) 245c serving as a flow rate controller (flow rate control mechanism) and a valve 245d serving as an opening/closing valve are provided at the dilution gas supply pipe 245a in order from an upstream side to a downstream side of the dilution gas supply pipe 245a. A dilution gas is supplied into the shower head 230 via the dilution gas supply pipe 245a provided with the MFC 245c and the valve 245d, the second gas supply pipe 244a and the RPU 244e. As described later, by adjusting an amount of the dilution gas, it is possible to adjust an amount of impurities in a sacrificial film such as the sacrificial film 104.

As the dilution gas, for example, a gas such as argon (Ar) gas and nitrogen (N₂) gas may be used. The nitrogen gas forms stronger chemical bonding with silicon than with argon, and is less likely to be desorbed in a modification process of the sacrificial film. Therefore, it is more preferable that the argon gas is used as the dilution gas.

The dilution gas supply system is constituted mainly by the dilution gas supply pipe 245a, the MFC 245c and the valve 245d. The dilution gas supply system may further include the dilution gas supply source 245b, the second gas supply pipe 244a and the RPU 244e. The dilution gas supply system may be included in the second gas supply system 244.

<Exhaust System>

An exhaust system of exhausting an inner atmosphere of the chamber 202 is constituted mainly by a process space exhaust system 261 of exhausting an inner atmosphere of the process space 205.

The process space exhaust system 261 includes an exhaust pipe 261a connected to the process space 205. The exhaust pipe 261a is spatially in communication with the process space 205. An APC (Automatic Pressure Controller) 261c of adjusting an inner pressure of the process space 205 to a predetermined pressure and a pressure detector 261d of detecting the inner pressure of the process space 205 are provided at the exhaust pipe 261a. The APC 261c includes an adjustable valve body (not shown). The APC 261c is configured to adjust the conductance of the exhaust pipe 261a in response to an instruction from a controller 280 which will be described later. A valve 261b is provided at an upstream side of the APC 261c provided at the exhaust pipe 261a. The exhaust pipe 261a, the valve 261b, the APC 261c and the pressure detector 261d are collectively referred to as the process space exhaust system 261.

A dry pump (DP) 278 is provided at a downstream side of the exhaust pipe 261a. The DP 278 exhausts the inner atmosphere of the process space 205 via the exhaust pipe 261a.

<Controller>

The substrate processing apparatus 200 includes the controller 280 configured to control the operations of components of the substrate processing apparatus 200. As shown in FIG. 4, the controller 280 includes at least a CPU (Central Processing Unit) 280a serving as an arithmetic unit, a RAM (Random Access Memory) 280b serving as a temporary memory device, a memory device 280c and a transmission/reception part 280d. The controller 280 is connected to the components of the substrate processing apparatus 200 via the transmission/reception part 280d, calls a program or a recipe from the memory device 280c in accordance with an instruction of a host controller or a user, and controls the operations of the components of the substrate processing apparatus 200 according to the contents of the instruction. The controller 280 may be embodied by a dedicated computer or as a general-purpose computer. According to the embodiments, the controller 280 may be embodied by preparing an external memory device 282 and installing the program onto the general-purpose computer using the external memory device 282. For example, the external memory device 282 may include a magnetic tape, a magnetic disk such as a flexible disk and a hard disk, an optical disk such as a CD and a DVD, a magneto-optical disk such as MO and a semiconductor memory such as a USB memory (USB flash drive) and a memory card. The means for providing the program to the computer is not limited to the external memory device 282. The program may be supplied to the computer using communication means such as the Internet and a dedicated line. The program may be provided to the computer without using the external memory device 282 by receiving the information (that is, the program) from a host apparatus 270 via a transmission/reception part 283. A user can input an instruction to the controller 280 using an input/output device 281 such as a keyboard and a touch panel.

The memory device 280c or the external memory device 282 may be embodied by a non-transitory computer readable recording medium. Hereafter, the memory device 280c and the external memory device 282 are collectively or individually referred to as the recording medium. In the present specification, the term “recording medium” may refer to only the memory device 280c, may refer to only the external memory device 282 or may refer to both of the memory device 280c and the external memory device 282.

<Substrate Processing>

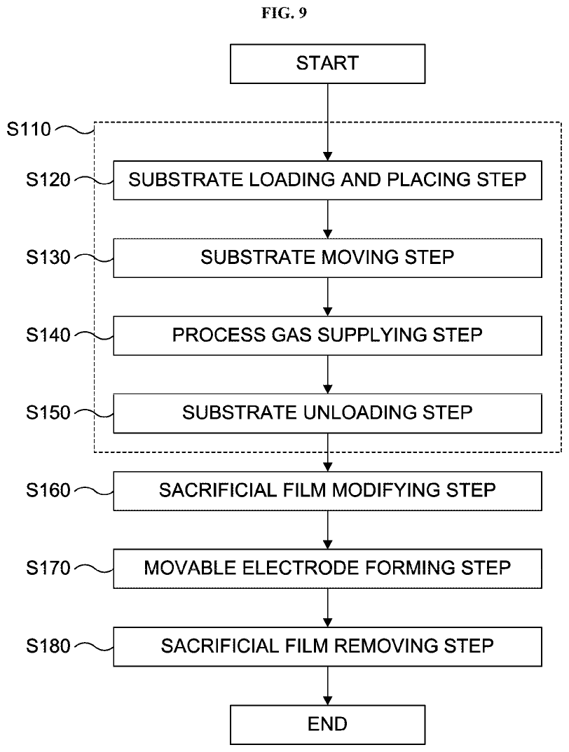

Hereinafter, an example of a substrate processing (film-forming process) of forming the sacrificial film 104 on the substrate 100, which is a part of manufacturing processes of a semiconductor device, will be described with reference to FIG. 9. FIG. 9 is a flow chart schematically illustrating the substrate processing according to the embodiments described herein. For example, the substrate processing is performed by using the substrate processing apparatus 200. Hereinafter, the operations of the components of the substrate processing apparatus 200 are controlled by the controller 280.

In addition, a process of modifying the sacrificial film 104 (also referred to as a “sacrificial film modifying process”) will be described. Since an apparatus configured to modify the sacrificial film 104 may be a general plasma processing apparatus such as a parallel plate type apparatus, the description of the apparatus will be omitted.

<Sacrificial Film Forming Process S110>

In the sacrificial film forming process S110, the substrate processing apparatus 200 shown in FIG. 3 is used. For example, the TEOS gas is used as the first process gas and the O₂ gas is used as the second process gas. A specific example of the sacrificial film forming process S110 will be described below.

<Substrate Loading and Placing Step S120>

The substrate support table 212 of the substrate processing apparatus 200 is lowered to the position for transferring the substrate 100 (that is, the substrate transfer position described above), and the lift pins 207 penetrate the through-holes 214 of the substrate support table 212. As a result, the lift pins 207 protrude from the surface of the substrate support table 212 with a predetermined height. In parallel with the operations described above, an inner atmosphere of the transfer space 206 is exhausted to adjust an inner pressure of the transfer space 206 to a pressure equal to or less than a pressure of the adjacent vacuum transfer chamber (not shown).

Subsequently, the gate valve 149 is opened to spatially connect the vacuum transfer chamber (not shown) to the transfer space 206. Then, the substrate 100 is loaded (transferred) into the transfer space 206 from the vacuum transfer chamber by a vacuum transfer robot (not shown).

The substrate 100 in the processing state shown in FIG. 1A is transferred (loaded) into the transfer space 206. Therefore, the control electrode 101, the pedestal 102 and the counter electrode 103 are formed on the substrate 100.

<Substrate Moving Step (Moving Substrate to Substrate Processing Position) S130>

After a predetermined time elapses, the substrate support table 212 is elevated to transfer the substrate 100 onto the substrate placing surface 211, and then further elevated until the substrate 100 is at the substrate processing position as shown in FIG. 3.

Subsequently, the sacrificial film 104 is formed as follows. For example, a silicon oxide film (also referred to as a “SiO film”) is formed as the sacrificial film 104.

<Process Gas Supplying Step S140>

After the substrate support table 212 is elevated to the substrate processing position, the inner pressure of the process space 205 is adjusted to a predetermined pressure by exhausting the inner atmosphere of the process space 205 via the exhaust pipe 262.

While adjusting the inner pressure of the process space 205 to the predetermined pressure, the substrate 100 is heated such that a temperature of the substrate 100 is adjusted to a predetermined temperature. For example, the predetermined temperature may range from 500° C. to 600° C. When the temperature of the substrate 100 reaches the predetermined temperature, the TEOS gas in a non-plasma state, i.e., not in a plasma state is supplied through the first gas supply system 243. In parallel with supplying the TEOS gas, the oxygen (O₂) gas in a plasma state is supplied through the second gas supply system 244. The O₂ gas is activated (excited) into the plasma state by the RPU 244e. The TEOS gas in the non-plasma state and the oxygen gas in the plasma state react in the buffer space 234 and the process space 205, and reaction products generated thereby are deposited on the substrate 100 to form the sacrificial film 104 as shown in FIG. 5.

As shown in FIG. 5, the sacrificial film 104 formed in the process gas supplying step S140 is a carbon-containing SiO film containing silicon components and carbon components originally contained in the TEOS gas and oxygen (O) components originally contained in the O₂ gas. Instead of the TEOS gas, a gas containing silicon components and boron (B) components may be used as the first process gas. When the gas containing the silicon components and the boron components is used, in FIG. 5, a boron-containing SiO film containing the boron components is formed in place of the carbon components.

The TEOS gas is not decomposed to a plasma level. Therefore, the carbon components are vaporized in a small amount as in a comparative example described later, so that only a small amount of the carbon components is vaporized to be exhausted from the process space 205. That is, a lot of the carbon components are present in the process space 205 when the sacrificial film 104 is formed. Therefore, the sacrificial film 104 contains a large amount of the carbon components.

After a predetermined time elapses and a carbon-containing SiO film with a desired thickness is formed, the supply of each of the process gases is stopped.

<Substrate Unloading Step S150>

After the sacrificial film 104 with a desired film thickness is formed, the substrate support table 212 is lowered such that the substrate 100 is moved to the substrate transfer position. After moving the substrate 100 to the substrate transfer position, the substrate 100 is unloaded (transferred) out of the transport space 206.

<Sacrificial Film Modifying Step S160>

Subsequently, a sacrificial film modifying step S160 of modifying the sacrificial film 104 (that is, the sacrificial film modifying process) will be described. The sacrificial film modifying step S160 is performed by using a general single-wafer type plasma apparatus such as a parallel plate type apparatus. Therefore, the description of the general single-wafer type plasma apparatus will be omitted.

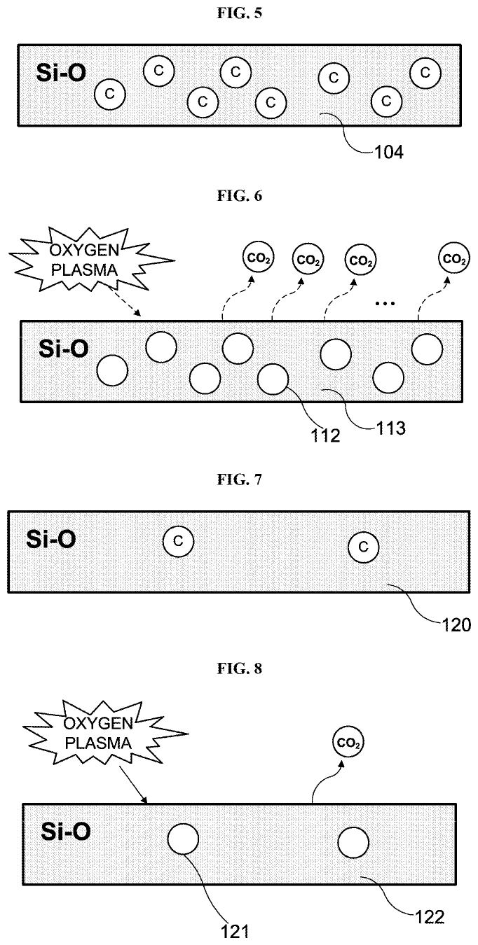

First, the substrate 100 is loaded (transferred) into a process chamber of the general single-wafer type plasma apparatus. After loading the substrate 100, as shown in FIG. 6, an oxygen-containing gas containing oxygen components is activated (excited) into a plasma state and radiated (supplied) onto the sacrificial film 104.

The oxygen components in the radiated plasma (oxygen plasma) and the carbon components in the sacrificial film 104 react with each other to desorb the carbon components from the sacrificial film 104. Holes 112 are formed in the sacrificial film 104 at portions from which the carbon components are desorbed. Therefore, the sacrificial film 104 is modified into a film (also referred to as a “modified film”) 113 containing the holes 112.

In addition, the desorbed carbon components react with the oxygen components in the plasma (oxygen plasma) to generate CO₂ gas and are exhausted.

After the substrate 100 is processed by the oxygen plasma for a predetermined time, the substrate 100 is unloaded out of the general single-wafer type plasma apparatus.

As described above, by forming the holes 112, a density of the sacrificial film 104 is lowered and the strength of the sacrificial film 104 is also lowered. Since the strength of the sacrificial film 104 is lowered, it is possible to increase the wet etching rate of the sacrificial film 104.

<Movable Electrode Forming Step S170>

Thereafter, similar to the processing states as shown in FIGS. 1F through 2C, the movable electrode 111 is formed on the sacrificial film 104 (that is, the modified film 113) modified in the sacrificial film modifying step S160.

<Sacrificial Film Removing Step S180>

Thereafter, similar to the processing state as shown in FIG. 2D, the sacrificial film 104 (that is, the modified film 113) is removed after the movable electrode 111 is formed.

According to the embodiments, the first gas supply pipe 234a is connected (joined) to the second gas supply pipe 244a at a downstream side of the RPU 244. Hereinafter, the reasons are explained. First, as the comparative example, the problems that arise when the first gas supply pipe 234a is connected to the second gas supply pipe 244a at an upstream side of the RPU 244e will be described.

The sacrificial film 120 formed according to the comparative example will be described with reference to FIG. 7. According to the comparative example, the first gas supply pipe 234a is connected to the second gas supply pipe 244a at the upstream side of the RPU 244e. Therefore, the TEOS serving as the first process gas is supplied to the process space 205 via the RPU 244e. When the sacrificial film 120 is formed, the second process gas is supplied in parallel with the first process gas in order to react with the first process gas.

Therefore, when the first process gas and the second process gas pass through the RPU 244e, both gases are activated into a plasma state and decomposed. As a result, the silicon components, the carbon components and the oxygen components are uniformly present in the buffer space 234 in a decomposed state.

According to the comparative example, a part of the carbon components reacts with the oxygen components to generate CO₂ gas, and does not contribute to the formation of the sacrificial film. Therefore, as shown in FIG. 7, the sacrificial film of the comparative example contains less carbon components than the sacrificial film of the embodiments. Therefore, even though the sacrificial film 120 is modified by desorbing the carbon components as described above and a modified film 112 is formed as shown in FIG. 8, the number of holes 121 in the modified film 112 according to the comparative example is smaller than the number of the holes 112 in the modified film 113 according to the embodiments.

As described above, according to the comparative example, only a small number of the holes 121 are formed. Therefore, it is difficult to reduce a density of the sacrificial film 120. That is, a wet etching rate of the sacrificial film 120 cannot be increased.

According to the comparative example, since a carbon-containing SiO film is formed by recombination of each of the components after being decomposed into each of the components by the plasma (oxygen plasma), the strength of chemical bonding between each of the components is increased. When the strength of chemical bonding is increased, it is necessary to supply the oxygen plasma in a high energy state in order to remove the carbon components in the sacrificial film modifying step of the comparative example. In order to generate the oxygen plasma in the high energy state, it is necessary to additionally prepare such components as an electrode corresponding to the oxygen plasma in the high energy state. Therefore, it is not preferable since the cost increases.

However, according to the present embodiments, the first gas supply pipe 234a is provided at the downstream side of the RPU 244e. By providing the first gas supply pipe 234a at the downstream side of the RPU 244e, the first process gas is not decomposed by the RPU 244e, so that the silicon components and the carbon components react with the oxygen plasma in the process space 205 while maintaining the bonding between the silicon components and the carbon components. Therefore, a lot of the carbon components are added to the sacrificial film 104. As a result, it is possible to form a large number of the holes 112 in the subsequent sacrificial film modifying step S160, and it is also possible to increase the wet etching rate.

In addition, according to the embodiments, an amount (also referred to as a “supply amount”) of the dilution gas supplied to the process space 205 may be adjusted. By adjusting the supply amount of the dilution gas, it is possible to adjust the amount of the carbon components contained in the sacrificial film 104.

Specifically, when the supply amount of the dilution gas is increased, the number of collisions between the dilution gas and the oxygen plasma is increased and a deactivation amount of the oxygen plasma is increased. Therefore, the CO₂ gas is hardly generated. Since a lot of the carbon components are supplied to the substrate 100, the amount of the carbon components in the sacrificial film 104 increases. As a result, it is possible to increase the wet etching rate.

On the other hand, when the supply amount of the dilution gas is decreased, the number of collisions between the dilution gas and the oxygen plasma is decreased and the oxygen plasma can maintain the high energy state. Therefore, the CO₂ gas is easily generated. That is, a lot of the carbon components are discharged as a gas. As a result, the amount of the carbon component in the sacrificial film 104 is decreased, and it is possible to decrease the wet etching rate.

As described above, it is possible to adjust the wet etching rate by adjusting the supply amount of the dilution gas. Therefore, it is possible to set (adjust) a concentration of an etchant to an optimum condition during the wet etching process.

As the dilution gas, the argon (Ar) gas or the N₂ gas may be used. More preferably, the Ar gas is used. When the sacrificial film 104 is formed, components in the dilution gas may be contained in the carbon-containing SiO film. The nitrogen (N) components tend to form stronger chemical bonding with silicon than argon (Ar) components. Therefore, if the N₂ gas is used as the dilution gas, a carbon-containing SiO film bonded with nitrogen is formed. This means that a film containing therein stronger chemical bonding is formed, thereby decreasing the wet etching rate.

Since argon components contained in the Ar gas do not form strong chemical bonding with silicon, the argon components are not added into the carbon-containing SiO film. That is, it is possible to increase the wet etching rate when the Ar gas is used as the dilution gas as compared with the wet etching rate when the N₂ gas is used as the dilution gas.

### Other Embodiments

While the technique is described in detail by way of the above-described embodiments, the above-described technique is not limited thereto. The above-described technique may be modified in various ways without departing from the gist thereof.

For example, the above-described embodiments are described by way of an example in which the TEOS gas is used as the first element-containing gas (first process gas) and the oxygen gas is used as the second element-containing gas (second process gas) to form the SiO film by the film-forming process performed by the substrate processing apparatus. However, the above-described technique is not limited thereto. For example, a gas containing the impurities may be used as the first process gas.

According to some embodiments in the present disclosure, it is possible to form the sacrificial film with a high wet etching rate so as to obtain the wet etching selectivity with respect to the movable electrode when manufacturing the cantilever structure sensor.

What is claimed is:

1. A method of manufacturing a semiconductor device comprising:
(a) loading a substrate comprising a control electrode, a pedestal and a counter electrode formed thereon into a process chamber; and
(b) forming a sacrificial film containing impurities on the control electrode, the pedestal and the counter electrode by supplying a first process gas in a non-plasma state containing the impurities and silicon to the process chamber through a first gas supply pipe together with supplying a second process gas in a plasma state containing oxygen to the process chamber through a second gas supply pipe.

2. The method of claim 1, wherein the impurities comprise carbon or boron.

3. The method of claim 2, wherein a dilution gas supply pipe configured to supply a dilution gas is connected to the second gas supply pipe, and a supply amount of the dilution gas is adjusted in (b).

4. The method of claim 3, wherein the dilution gas comprises argon gas.

5. The method of claim 4, further comprising:
(c) modifying the sacrificial film by desorbing the impurities contained in the sacrificial film after performing (b);
(d) forming a movable electrode on the sacrificial film after performing (c); and
(e) removing the sacrificial film after performing (d).

6. The method of claim 3, further comprising:
(c) modifying the sacrificial film by desorbing the impurities contained in the sacrificial film after performing (b);
(d) forming a movable electrode on the sacrificial film after performing (c); and
(e) removing the sacrificial film after performing (d).

7. The method of claim 2, further comprising:
(c) modifying the sacrificial film by desorbing the impurities contained in the sacrificial film after performing (b);
(d) forming a movable electrode on the sacrificial film after performing (c); and
(e) removing the sacrificial film after performing (d).

8. The method of claim 7, wherein a plasma generator is provided at the second gas supply pipe, and the first gas supply pipe is connected to the second gas supply pipe at a downstream side of the plasma generator.

9. The method of claim 2, wherein a plasma generator is provided at the second gas supply pipe, and the first gas supply pipe is connected to the second gas supply pipe at a downstream side of the plasma generator.

10. The method of claim 1, wherein a dilution gas supply pipe configured to supply a dilution gas is connected to the second gas supply pipe, and a supply amount of the dilution gas is adjusted in (b).

11. The method of claim 10, wherein the dilution gas comprises argon gas.

12. The method of claim 11, further comprising:
(c) modifying the sacrificial film by desorbing the impurities contained in the sacrificial film after performing (b);
(d) forming a movable electrode on the sacrificial film after performing (c); and
(e) removing the sacrificial film after performing (d).

13. The method of claim 12, wherein a plasma generator is provided at the second gas supply pipe, and the first gas supply pipe is connected to the second gas supply pipe at a downstream side of the plasma generator.

14. The method of claim 11, wherein a plasma generator is provided at the second gas supply pipe, and the first gas supply pipe is connected to the second gas supply pipe at a downstream side of the plasma generator.

15. The method of claim 10, further comprising:
(c) modifying the sacrificial film by desorbing the impurities contained in the sacrificial film after performing (b);
(d) forming a movable electrode on the sacrificial film after performing (c); and
(e) removing the sacrificial film after performing (d).

16. The method of claim 15, wherein a plasma generator is provided at the second gas supply pipe, and the first gas supply pipe is connected to the second gas supply pipe at a downstream side of the plasma generator.

17. The method of claim 10, wherein a plasma generator is provided at the second gas supply pipe, and the first gas supply pipe is connected to the second gas supply pipe at a downstream side of the plasma generator.

18. The method of claim 1, further comprising:
(c) modifying the sacrificial film by desorbing the impurities contained in the sacrificial film after performing (b);
(d) forming a movable electrode on the sacrificial film after performing (c); and
(e) removing the sacrificial film after performing (d).

19. The method of claim 18, wherein a plasma generator is provided at the second gas supply pipe, and the first gas supply pipe is connected to the second gas supply pipe at a downstream side of the plasma generator.

20. The method of claim 1, wherein a plasma generator is provided at the second gas supply pipe, and the first gas supply pipe is connected to the second gas supply pipe at a downstream side of the plasma generator.
